(19) United States
(12) Patent Application Publication
(10) Pub. No.: US 2025/0328083 A1
(43) Pub. Date: Oct. 23, 2025

(54) SIMULATION METHOD FOR PROGRAMMABLE ILLUMINATION SYSTEM AND SOURCE MASK OPTIMIZATION METHOD

(71) Applicant: Wuhan Yuwei Optical Software Co., Ltd., Hubei (CN)

(72) Inventors: Haiqing Wei, Hubei (CN); Shiyuan Liu, Hubei (CN)

(73) Assignee: Wuhan Yuwei Optical Software Co., Ltd., Hubei (CN)

(21) Appl. No.: 18/754,086

(22) Filed: Jun. 25, 2024

(30) Foreign Application Priority Data
Apr. 17, 2024 (CN) 202410459717.6

(51) Int. Cl. G03F 7/00

(52) U.S. Cl. CPC G03F 7/705; G03F 7/70516

(57) ABSTRACT

The present invention relates to a simulation method for a programmable illumination system and a source mask optimization method. The simulation method includes: calibrating the parameters of the source map transfer model (SMTM) in the first simulation model based on the ordered source map (OSM) sample and the actual processing result; wherein the actual processing result is obtained by inputting the OSM sample to the physical lithographic tool and monitoring the processing process of the physical lithographic tool, the first simulation model is configured to output simulation processing results corresponding to the actual processing results, the first simulation model at least includes the SMTM; and the calibrated SMTM is used as a programmable illumination system (PIS) model. In the invention, by using reference data to calibrate the parameters of the SMTM in the first simulation model to obtain the PIS model.

### CROSS-REFERENCE TO RELATED APPLICATION

This application claims the priority benefit of China application serial no. 202410459717.6, filed on Apr. 17, 2024. The entirety of the above-mentioned patent application is hereby incorporated by reference herein and made a part of this specification.

### BACKGROUND

### Technical Field

The present disclosure belongs to the technical field of computational lithography, and more specifically, relates to a simulation method for a programmable illumination system and a source mask optimization method.

### Description of Related Art

In integrated circuit (IC) manufacturing, as feature sizes are gradually reduced, Source Mask Optimization (SMO) technology has become one of the key technologies to improve the resolution. In SMO technology, the source and mask are collaboratively optimized, and the source is normally implemented on the actual physical lithographic tool by a Programmable Illumination System (PIS). Due to the constraints of processing technology, distortion will occur in PIS when realizing the Ordered Source Map (OSM), thus the Realized Source Map (RSM) is often different from the OSM. For users other than PIS manufacturers and lithography machine manufacturers, such as IC manufacturers, wafer fab engineers, and Optical Proximity Correction (OPC) tool developers as well as users, the implementation process of PIS for sources is unknown. The current OPC tools do not contain any module for PIS characteristics since it cannot be obtained. The distortion of PIS hardware will cause the final exposure effect on the physical lithographic tools to fail to meet expectations even if the SMO is pursued, thus affecting the yield of the entire IC manufacturing.

Luckily, for each lithographic tool, or even each series, the mapping relationship from OSM to RSM is fixed, which is called as the source map transfer function (SMTF), even though it is always unknown to the IC manufacturers, wafer fab engineers, and Optical Proximity Correction (OPC) tool developers. There are some analytical properties of this mapping relationship in terms of mathematical properties, such as that it is at least continuous or even differentiable. The continuity of the SMTF means that the input and output can be characterized in the form of the image or the vectors of orthogonal polynomial kernels, and regardless of the above form, there is a mathematical mapping relationship between the input and output, namely source map transfer function (SMTF). This ensures that the SMTF implemented by the physical PIS is trainable and learnable. Therefore, the SMTF implemented by the PIS can be simulated, thus a virtual computer model or system can be built to simulate the characteristics of PIS.

### SUMMARY

The purpose of the disclosure is to establish and calibrate the Source Map Transfer Model (SMTM), as to develop a separate PIS model, and further apply to SMO, in the hope of solving the problem of undesirable final exposure effect on the physical lithographic tools caused by distortion of PIS in the existing technology. This disclosure provides a solution for users other than PIS manufacturers and lithographic tool manufacturers, such as IC manufacturers, wafer fab engineers, and Optical Proximity Correction (OPC) tool developers as well as users, to avoid the exposure quality reduction and process window narrowing problem by the PIS distortion.

In order to achieve the above purpose, in the first aspect, the present disclosure provides a simulation method for a programmable illumination system, including:

Calibrating the parameters of the source map transfer model (SMTM) in the first simulation model based on the ordered source map (OSM) sample and the actual processing result; wherein the actual processing result is obtained by inputting the OSM sample to the physical lithographic tool and monitoring the processing process of the tool, wherein the physical lithographic tool is equipped with a programmable illumination system (PIS) entity, and the first simulation model is configured to output a simulation processing result corresponding to the actual processing result, while the first simulation model at least includes the SMTM.

The calibrated SMTM is used as a PIS model, and the PIS model is used to simulate the physical PIS entity.

In a possible implementation, when the realized source map (RSM) output by the physical PIS entity is able to be monitored, the actual processing result is the measured RSM of the physical PIS entity, the first simulation model is the SMTM, and the simulation processing result is the RSM output by the SMTM.

The step of calibrating the parameters of the source map transfer model (SMTM) in the first simulation model based on the ordered source map (OSM) sample and actual processing result includes:

Continuously optimizing the SMTM based on the OSM sample and the measured RSM of the physical PIS entity until the iteration stop condition is met.

The step of optimizing the SMTM includes:
Inputting the OSM sample to the SMTM to obtain the RSM output by the SMTM;
Comparing the difference between the measured RSM of the physical PIS entity and the RSM output by the SMTM to determine the first difference comparison result;
In the case where the first difference comparison result indicates that the iteration stop condition is not met, adjusting the parameters of the SMTM based on the first difference comparison result; in the case where the first difference comparison result indicates that the iteration stop condition is met, determining the calibrated SMTM.

In a possible implementation, the SMTM is a neural network model. The step of comparing the difference between the measured RSM of the physical PIS entity and the RSM output by the SMTM to determine the first difference comparison result includes:
Determining the first difference between the measured RSM of the physical PIS entity and the RSM output by the SMTM; evaluating the first difference based on a loss function and determining the loss value as the first difference comparison result;
In the case where the first difference comparison result indicates that the iteration stop condition is not met, the step of adjusting the parameters of the SMTM based on the first difference comparison result includes:
Adjusting the network neuron weights of the neural network model through back propagation based on the loss value.

In a possible implementation, in the case where the realized source map (RSM) output by the physical PIS entity is not able to be monitored, the first simulation model includes a SMTM, an optical exposure model and a resist model cascaded in sequence, and the simulation processing result is the simulated silicon wafer result output by the resist model.

Calibrating the parameters of the source map transfer model (SMTM) in the first simulation model based on the ordered source map (OSM) sample and the actual processing result includes:

Continuously optimizing the SMTM based on the OSM sample and the actual silicon wafer result output by the physical lithographic tool until the iteration stop condition is met.

The step of optimizing the SMTM includes:
Inputting the OSM sample into the first simulation model to obtain the simulated silicon wafer result output by the resist model;
Comparing the difference between the actual silicon wafer result output by the physical lithographic tool and the simulated silicon wafer result output by the resist model, and determining a second difference comparison result;
In the case where the second difference comparison result indicates that the iteration stop condition is not met, adjusting the parameters of the SMTM based on the second difference comparison result; in the case where the second difference comparison result indicates that the iteration stop condition is met, determining the calibrated SMTM.

In the second aspect, the present disclosure further provides a source mask optimization (SMO) method, including:
Determining a target silicon wafer result;
Performing source mask optimization (SMO) based on the target silicon wafer result and the second simulation model to obtain the optimized ordered source map (OSM) and the optimized mask;
Wherein the second simulation model is constructed based on the PIS model, the optical exposure model and the resist model, and the PIS model is obtained by applying any one of the above simulation methods for the programmable illumination system.

In a possible implementation, the second simulation model includes a first-stage simulation model and a second-stage simulation model, the first-stage simulation model is constructed based on the optical exposure model and the resist model, and the PIS model serves as the second-stage simulation model.

The step of performing source mask optimization based on the target silicon wafer result and the second simulation model to obtain the optimized ordered source map (OSM) and the optimized mask includes:
Performing source mask optimization based on the target silicon wafer result and the first-stage simulation model to obtain the target RSM and the optimized mask;
Obtaining the optimized OSM through iterative optimization based on the target RSM and the second-stage simulation model.

In a possible implementation, the step of obtaining the optimized OSM through iterative optimization based on the target RSM and the second-stage simulation model includes:
Inputting the target OSM into the PIS model, obtaining the RSM output by the PIS model, wherein the initial target OSM is the target RSM;
Comparing the difference between the RSM output by the PIS model and the target RSM, and determining the second-stage difference comparison result;
In the case where the second-stage difference comparison result indicates that the iteration stop condition is not met, adjusting the target OSM based on the second-stage difference comparison result; alternatively, in the case where the second-stage difference comparison result indicates that the iteration stop condition is met, determining the target OSM as the optimized OSM.

In a possible implementation, the second simulation model consists of the PIS model, the optical exposure model and the resist model cascaded in sequence. The step of performing source mask optimization based on the target silicon wafer result and the second simulation model to obtain the optimized ordered source map (OSM) and the optimized mask includes:
Inputting the target OSM to the PIS model, inputting the output amount of the PIS model and the target mask to the optical exposure model, inputting the output amount of the optical exposure model to the resist model to obtain the simulated silicon wafer result output by the resist model;
Comparing the difference between the simulated silicon wafer result and the target silicon wafer result, and determining the third difference comparison result;
In the case where the third difference comparison result indicates that the iteration stop condition is not met, adjusting the target OSM and the target mask based on the third difference comparison result; alternatively, in the case where the third difference comparison result indicates that the iteration stop condition is met, determining the target OSM as the optimized OSM and determining the target mask as the optimized mask.

In a third aspect, the present disclosure provides an electronic device, including: at least one memory for storing a program; at least one processor for executing the program stored in the memory. In the case where the program stored in the memory is executed, the processor is configured to execute the method described in the first aspect or any possible implementation in the first aspect, or the processor is configured to execute the method described in the second aspect or any possible implementation in the second aspect.

In a fourth aspect, the present disclosure provides a computer-readable storage medium. The computer-readable storage medium stores a computer program. When the computer program is run on a processor, the processor is enabled to execute the method described in the first aspect or any possible implementation in the first aspect, or the processor is enabled to execute the method described in the second aspect or any possible implementation in the second aspect.

Generally speaking, compared with the existing technology, the above technical solution conceived through the disclosure has the following advantageous effects:

Before calibrating the parameters of the source map transfer model (SMTM) in the first simulation model, the output of a observable section may be determined as the actual processing result based on the observable condition of each section in the processing process of the physical lithographic tool, thereby determining the corresponding first simulation model. For example, if the measured RSM of the physical PIS entity of the physical lithographic tool is able to be observed or monitored, the measured RSM of the physical PIS entity may be used as the actual processing result. Correspondingly, the constructed first simulation model uses the OSM sample as the simulation input and use the RSM as the simulation processing result. For example, if the RSM is able to be observed or monitored and the actual silicon wafer result output by the physical lithographic tool is able to be observed, the actual silicon wafer result may be used as the actual processing result. Correspondingly, the constructed first simulation model uses the OSM sample as the simulation input and uses the silicon wafer result as the simulation output. After constructing the first simulation model and determining the reference data, including multiple OSM samples and the actual processing results corresponding to various OSM samples, the reference data may be used to calibrate the parameters of the SMTM in the first simulation model to obtain the calibrated SMTM as the PIS model, and the PIS model may be used to simulate the physical PIS entities with PIS characteristics. In the case where the PIS characteristics are obtained, SMO is utilized to optimize the source to effectively avoid the impact caused by distortion of PIS hardware on the exposure effect on the physical lithographic tool, thereby ensuring the yield of IC manufacturing.

### BRIEF DESCRIPTION OF THE DRAWINGS

FIG. 1 is a schematic diagram of a comparison between a physical PIS machine and a PIS model according to an embodiment of the present disclosure.

FIG. 2 is a schematic flow chart of a PIS model simulation method according to an embodiment of the present disclosure.

FIG. 3 is a schematic diagram of SMTM when RSM is observable according to an embodiment of the present disclosure.

FIG. 4 is a schematic diagram of SMTM based on a neural network according to an embodiment of the present disclosure.

FIG. 5 is a schematic diagram of SMTM when RSM is unobservable according to an embodiment of the present disclosure.

FIG. 6 is a schematic flow chart of a source mask optimization method according to an embodiment of the present disclosure.

FIG. 7 is a schematic flow chart of a two-stage SMO according to an embodiment of the present disclosure.

FIG. 8 is a schematic flow chart of SMO involving a PIS model according to an embodiment of the present disclosure.

FIG. 9 is a schematic structural diagram of an electronic device according to an embodiment of the present disclosure.

In all the drawings, the same reference numbers are used to refer to the same elements or structures, including:

D1 represents OSM; D11 represents the OSM image; D2 represents RSM; D3 represents the measured RSM; D4 represents simulated RSM; D41 represents simulated RSM image; D5 represents mask; D6 represents actual silicon wafer result; D7 represents simulated silicon wafer results; D8 represents target silicon wafer result; D9 represents objective RSM; P1 represents physical PIS entity; P2 represents PIS model; P3 represents SMTM; P31 represents SMTM established by using the neural network; P4 represents actual optical exposure system; P5 represents optical exposure model; P6 represents the actual resist reaction; P7 represents resist model; C1 represents comparison of the measured RSM with the simulated RSM; C2 represents comparison between the actual wafer results with the simulated wafer results.

### DESCRIPTION OF THE EMBODIMENTS

To facilitate understanding of each embodiment of the present disclosure, some background knowledge is introduced first as follows.

For users other than PIS manufacturers and lithographic tool manufacturers, such as IC manufacturers, wafer fab engineers, and Optical Proximity Correction (OPC) tool developers as well as general users, the implementation process of PIS for source is unknown. It was found during the engineering practice conducted by the applicant of the present disclosure that the mapping relationship from OSM to RSM implemented by each lithographic tool, or even each series, is fixed, and the mapping is defined as the Source Map Transfer Function (SMTF). In terms of mathematical properties, there are some good analytical properties in the mapping relationship. For example, SMTF is at least continuous and even differentiable. The continuity of SMTF means that the input and the output of SMTF may be expressed in the form of image characterization or coefficient vector characterization of an orthogonal kernel function. No matter which of the above characterization is used for expression, there is a mathematical mapping relationship between the input and the output, namely SMTF. Therefore, it is ensured that the SMTF implemented by the physical PIS entity is trainable and learnable. Therefore, the SMTF implemented may be simulated and modeled to simulate the characteristics of PIS.

In this regard, the disclosure provides a PIS simulation method, aiming to establish a separate PIS model to simulate the realization process of the PIS. The present disclosure further provides a source mask optimization method, in which the calibrated model is further applied to SMO, thereby providing a solution for users as IC manufacturers, wafer fab engineers, and OPC tool developers as well as general users. In this way, it is possible to avoid the problems of reduced exposure quality and narrowed process window caused by PIS distortion.

In order to make the purpose, technical solutions and advantages of the present disclosure clearer, the present disclosure will be further described in detail below with reference to the drawings and embodiments. It should be understood that the specific embodiments described here are only used to explain the present disclosure and are not used to limit the present disclosure.

The terms “first”, “second”, etc. in the description and claims herein are used to distinguish different objects, rather than to describe a specific order of objects. For example, the first difference comparison result, the second difference comparison result, etc. are used to distinguish different difference comparison results, but are not used to describe a specific order of the difference comparison results.

In the embodiments of the present disclosure, terms such as “exemplary” or “for example” are used to represent examples, illustrations or explanations. Any embodiment or design described as “exemplary embodiment” or “example” in the embodiments of the present disclosure is not to be construed as preferred or advantageous over other embodiments or designs. Rather, use of the words “exemplary” or “example” is intended to present the concept in a concrete manner.

In the description of the embodiments of the present disclosure, unless otherwise stated, the meaning of “a plurality of” refers to two or more, for example, a plurality of processing units refers to two or more processing units, etc.; a plurality of component refers to two or more components, etc.

To facilitate understanding, the English abbreviations and related technical terms involved in the embodiments of the present disclosure are first explained and described below.

(1) OPC: optical proximity correction;

(2) SMO: source mask optimization;

(3) PIS: programmable illumination system;

(4) OSM: ordered source map, referring to the ordered source map before entering PIS;

(5) RSM: realized source map, referring to the realized source map generated by PIS;

(6) In the present disclosure, the term “physical” is related to an entity, a physical object or a physical machine, and “virtual” or “model” is related to a computer or simulation;

(7) SMTF: source map transfer function;

(8) SMTM: source map transfer model, a model established for describing the SMTF of PIS. The calibrated SMTM may be used as a PIS model.

The embodiments of the present disclosure will be described below with reference to the drawings in the embodiments of the present disclosure.

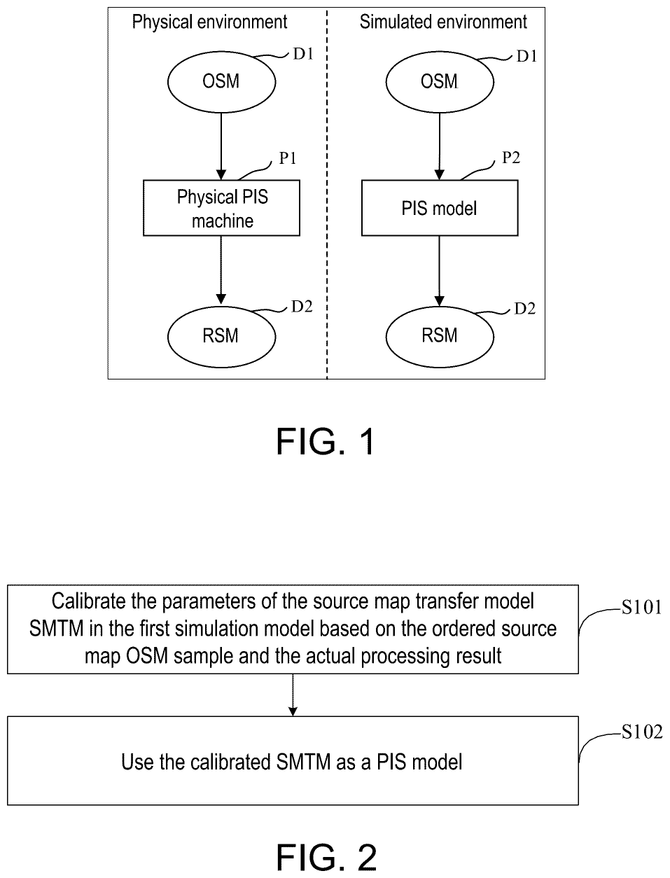

FIG. 1 is a schematic diagram of a comparison between the physical PIS and the PIS model according to an embodiment of the present disclosure. As shown in FIG. 1, in a physical environment, OSM is an input of a physical PIS (the programmable illumination system entity in the physical lithographic tool), and RSM is an output thereof. In the simulation environment, the PIS model is used to describe the mapping characteristics of the physical PIS, that is, SMTF. The same OSM serves as the input and RSM that is the same as the physical environment serves as the output.

The modeling process of the PIS model may be considered separately depending on whether the measured RSM of the physical PIS is able to be observed (will be explained later).

FIG. 2 is a schematic flow chart of a PIS simulation method according to an embodiment of the present disclosure. As shown in FIG. 2, the subject to be processed in the PIS simulation modeling method may be an electronic device, such as a server. The method includes the following steps S101 and S102.

Step S101: Calibrating the parameters of the source map transfer model (SMTM) in the first simulation model based on the ordered source map (OSM) sample and the actual processing result; wherein the actual processing result is obtained by inputting the OSM sample to the physical lithographic tool and monitoring the process of the physical lithographic tool, where the physical lithographic tool is equipped with a physical PIS. The first simulation model is configured to output the simulation result corresponding to the actual processing result. The first simulation model at least includes SMTM.

Step S102: Using the calibrated SMTM as a PIS model; wherein the PIS model is configured to simulate the physical PIS entity.

Specifically, the actual processing result may be one of a certain processing section among all the processing of the physical lithographic tool, or the one of the last processing section. The specific requirement is determined based on whether each processing section of the physical lithographic tool is able to be observed or monitored. If the result of a processing section is able to be observed or monitored, the result of this processing section may be used as the actual processing result; if the all the result of the processing sections cannot be observed or monitored, the result of the last processing section may be used as the actual processing result.

For example, the actual processing result may be realized source map (RSM) or actual silicon wafer result. If the measured RSM of the physical PIS of the physical lithographic tool is able to be monitored or observed, the measured RSM of the physical PIS may be used as the actual processing result. If the actual silicon wafer result output by the physical lithographic tool is able to be monitored, the actual silicon wafer result may be used as the actual processing result.

The data set (including OSM sample and corresponding actual processing result) related to the extent of coverage of the source map has a direct impact on the modeling accuracy of the PIS model. A plurality of OSM samples and the actual processing results corresponding to various OSM samples may be obtained in order to ensure the modeling accuracy of the PIS model. The plurality of OSM samples involve various source maps as many as possible that may be realized by the physical PIS. The model accuracy of the PIS model is ensured by calibrating the parameters of the source map transfer model (SMTM) in the first simulation model using the plurality of OSM samples and actual processing results corresponding to the plurality of OSM samples respectively.

The following is an analysis of the working principle of the PIS simulation method. Before calibrating the parameters of the source map transfer model SMTM in the first simulation model, the output of a observable section may be determined as the actual processing result based on the observable condition of each section in the processing of the physical lithographic tool, thereby determining the corresponding first simulation model. For example, if the measured RSM of the physical PIS entity of the physical lithographic tool is able to be monitored or observed, the measured RSM of the physical PIS entity may be used as the actual processing result. Correspondingly, the constructed first simulation model uses the OSM sample as the simulation input and uses RSM as the simulation output. For example, if the actual silicon wafer result output by the physical lithographic tool is able to be monitored, the actual silicon wafer result may be used as the actual processing result. Correspondingly, the constructed first simulation model uses the OSM sample as the simulation input and the silicon wafer result as the simulation output. After constructing the first simulation model and determining the reference data (including the plurality of OSM samples and the actual processing results corresponding to various OSM samples), the reference data may be used to calibrate the parameters of the SMTM in the first simulation model to obtain the calibrated SMTM, namely, PIS model, and the PIS model may be used to simulate physical characteristics of the PIS entities. In the case where the PIS characteristics are obtained, SMO is utilized to optimize the source to effectively avoid the impact caused by distortion of PIS on the exposure effect on the physical lithographic tool, thereby ensuring the yield of IC manufacturing.

It may be understood that, compared with SMO in the related art, the embodiment of the present disclosure takes the distortion of PIS into consideration, and differentiates the ordered source map (OSM) from the realized source map (RSM) implemented by PIS, which models and calibrates the physical PIS, and constructs the conversion relationship between OSM to RSM, thereby obtaining the calibrated SMTM (that is, the PIS model). The PIS model may be used in SMO to optimize the ordered source map, so that as the final SMO optimization result, OSM may be directly used as the input of the physical PIS. In this way, when IC manufacturers adopt the existing SMO source results as the source settings for physical PIS, in practice, the problem of undesirable lithography exposure results caused by distortion of the physical PIS may be solved, thereby effectively improving processing window ultimately.

In addition, during the establishment of the PIS model, the embodiment of the present disclosure takes into consideration the detectability of the RSM output by the actual physical PIS, so that the conditions where RSM is able to be directly detected and cannot be directly detected are both considered. The output of an observable section is determined as the actual processing result according to the observable condition of each section in the processing process of the physical lithographic tool, thereby determining the corresponding first simulation model. Furthermore, the parameters of the SMTM in the first simulation model are calibrated using the reference data to obtain the calibrated SMTM (that is, the PIS model). The PIS model may be configured to simulate the physical PIS entity. For IC manufacturers, the method provided above is practical and applicable.

In a possible implementation, when the measured RSM of the physical PIS entity is able to be observed, the actual processing result is the measured RSM of the physical PIS entity (that is, the RSM obtained through observing, which may be called “measured RSM”), the first simulation model is SMTM, and the simulation processing result is the RSM (that is, the RSM obtained through simulation, which may be called “simulated RSM”) output by SMTM.

Based on the OSM sample and the actual processing result, the step of calibrating the parameters of the SMTM in the first simulation model includes:

Continuously optimizing the SMTM based on the OSM sample and the measured RSM of the physical PIS entity until the iteration stop condition is met.

The step of optimizing the SMTM includes:
Inputting the OSM sample to the SMTM to obtain the RSM output by the SMTM;
Comparing the difference between the measured RSM of the physical PIS entity and the simulated RSM output by the SMTM to determine the first difference comparison result;
In the case where the first difference comparison result indicates that the iteration stop condition is not met, adjusting the parameters of the SMTM based on the first difference comparison result; in the case where the first difference comparison result indicates that the iteration stop condition is met, determining the calibrated SMTM.

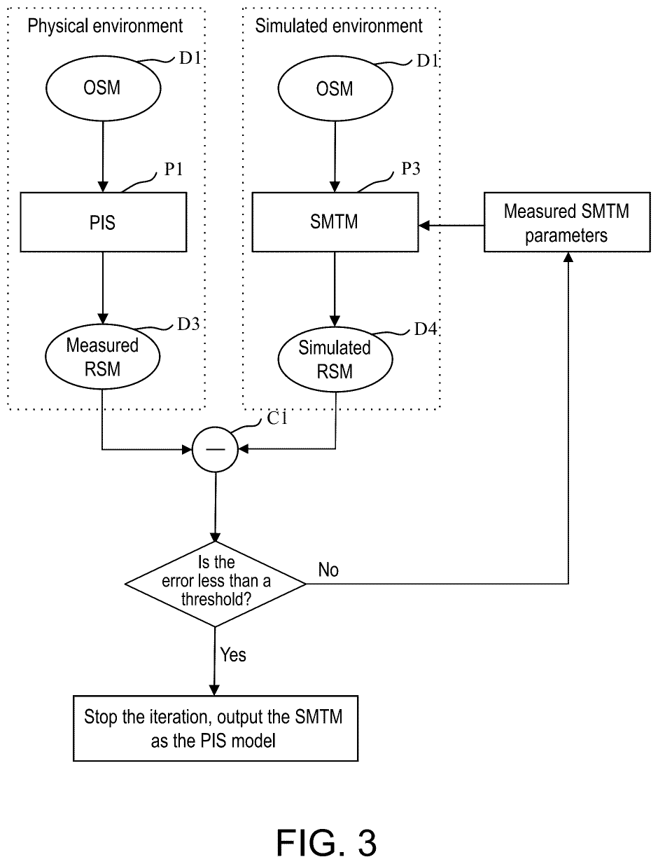

Example 1. FIG. 3 is a schematic diagram of SMTM modeling when RSM is observable according to an embodiment of the present disclosure. When the measured RSM of the physical PIS is able to be directly observed, the process shown in FIG. 3 may be used for modeling, wherein the OSM sample is used as the input into the physical PIS and SMTM respectively. The measured RSM of the physical PIS is compared with the simulated RSM output by the SMTM. According to the comparison result, the parameters in the SMTM are iteratively adjusted until the difference between the RSM output by the two is small enough, that is, the SMTF realized by the physical PIS is consistent with the one realized by the established model, then the established SMTM may be used as the PIS model. Specifically, when the measured RSM of the physical PIS is able to be directly observed, the PIS simulation method provided by the embodiment of the present disclosure includes the following steps S11 to step S15.

Step S11: Preliminarily establishing an SMTM model. The model may be, but is not limited to, a combination of various eigenvalues and eigenfunctions, and adjustable parameters may be involved.

Step S12: Collecting data sets related to input OSM samples and output RSM (measured RSM) as reference data through the physical PIS. The data should be OSM samples of a plurality of different types (the type here may characterize the source map), different configurations (the configuration here may indicate the configuration method of indicating the source map), and different parameters (the parameters here may be parameters related to source map). The plurality of OSM samples involve various source maps as many as possible that may be realized by the physical PIS. After inputting each OSM sample into PIS, the corresponding measured RSM is obtained. The data set related to the extent of coverage of the source map has a direct impact on the model accuracy of the PIS model. OSM samples and RSM, serving as the input and output of SMTM, may be characterized by but not limited to image characterization, or approximately orthogonal polynomials as basic functions, while the polynomials include but not limited to Zernike polynomials, Legendre polynomials, etc.

Step S13: Using each OSM sample in step S12 as input data. Each OSM sample serving as the input data to the SMTM in step S11, the simulated RSM is the output, and the simulated RSM in each group is differentiated from the measured RSM to make a comparison It is determined whether the difference (i.e., the first difference comparison result) is less than a predetermined threshold. If the difference is not less than the threshold, step S14 is performed; if the difference is less than the threshold, step S15 is performed.

Step S14: Adjusting the adjustable parameters in SMTM, updating SMTM, and performing step S13.

Step S15: Stopping the iteration and outputting SMTM as the PIS model.

In a possible implementation, SMTM is a neural network model. The step of comparing the difference between the measured RSM of the physical PIS entity and the simulated RSM output by the SMTM and determining the first difference comparison result includes:
Determining the first difference between the measured RSM of the PIS entity and the simulated RSM output by the SMTM; evaluating the first difference based on a loss function and determining the loss value as the first difference comparison result;
In the case where the first difference comparison result indicates that the iteration stop condition is not met, the step of adjusting the parameters of the SMTM based on the first difference comparison result includes:

Adjusting the weights of the neural network model through backpropagation based on the loss value.

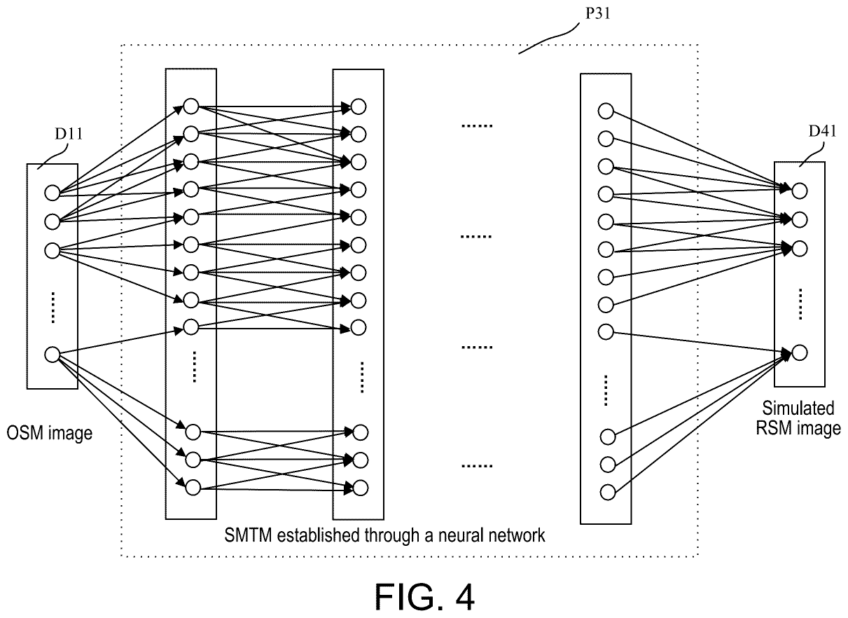

Example 2. FIG. 4 is a schematic diagram of SMTM modeling based on a neural network according to an embodiment of the present disclosure. Taking the input OSM sample and the output RSM as an example; exemplarily, both the input OSM sample and the output RSM are characterized by images. When the RSM of the physical PIS is able to be directly observed, the network structure shown in FIG. 4 may be adopted to establish the PIS model. Specifically, the PIS simulation method provided by an embodiment of the present disclosure includes the following steps S21 to S28.

Step S21: Establishing the SMTM neural network structure. The number and structure of the hidden layers are set according to the PIS characteristics and the source map characterization method. In the SMTM neural network structure, the input layer is the OSM images, the output layer is the RSM images, and the hidden layer performs image processing.

Step S22: Initializing the network neuron weights using a random initialization method.

Step S23: Collecting the data set of the input OSM images and the actual output RSM images through the physical PIS. The data should be multiple OSMs of different types, different configurations, and different parameters, and involve various source maps as many as possible that may be realized by the physical PIS. After inputting each OSM sample into PIS, the corresponding measured RSM is obtained. The data set related to the extent of coverage of the source map has a direct impact on the model accuracy of the PIS model.

Step S24: Defining the loss function as the difference between the measured RSM images and the simulated RSM images. The difference image (that is, the first difference) between the two may be evaluated using, but not limited to the 2-norms.

Step S25: Using each OSM image as the network input, performing forward propagation to obtain each simulated RSM image output by the network.

Step S26: Calculating the loss function and determining whether the loss value of the loss function (that is, the first difference comparison result) meets the iteration stop condition. If the result is negative, step S27 is performed. If the result is positive, step S28 is performed.

Step S27: Performing backpropagation based on the network error (that is, the loss value) calculated in step S26, updating the model by adjusting the network neuron weights, and performing step S25. The backpropagation performed may be but is not limited to the gradient descent method to update the network neuron weights.

Step S28: Stopping the iteration and outputting the network structure as the calibrated SMTM, that is, the PIS model.

In a possible implementation, in the case where the RSM output by the physical PIS entity cannot be observed, the first simulation model includes the SMTM, optical exposure model and resist model cascaded in sequence, and the simulated processing result is the simulated silicon wafer result output by the resist model (that is, the simulated silicon wafer surface result).

The step of calibrating the parameters of the SMTM in the first simulation model based on the OSM sample and actual processing result includes:

Continuously optimizing the SMTM based on the OSM sample and the actual silicon wafer result (that is, the measured silicon wafer surface exposure and development result) output by the physical lithographic tool until the iteration stop condition is met.

The step of optimizing the SMTM includes:
Inputting the OSM sample into the first simulation model to obtain the simulated silicon wafer result output by the resist model;
Comparing the difference between the measured silicon wafer of the physical lithographic tool and the simulated silicon wafer result output by the resist model, and determining the second difference comparison result;
In the case where the second difference comparison result indicates that the iteration stop condition is not met, adjusting the parameters of the SMTM based on the second difference comparison result; in the case where the second difference comparison result indicates that the iteration stop condition is met, determining the calibrated SMTM.

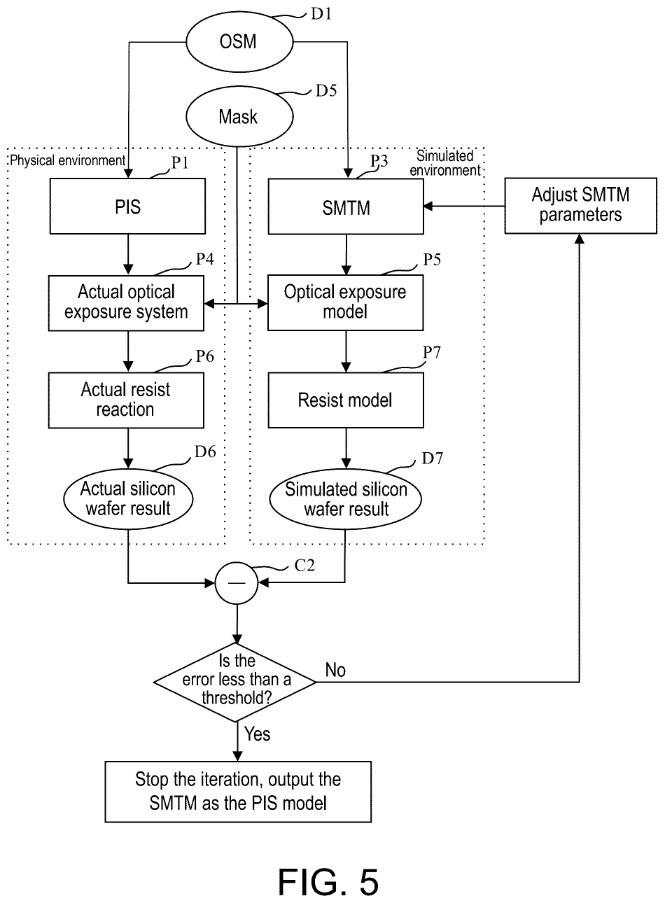

Example 3. FIG. 5 is a schematic diagram of SMTM modeling when the RSM is unobservable according to an embodiment of the present disclosure. When the measured RSM of the physical PIS cannot be directly observed, the process shown in FIG. 5 may be used for PIS modeling, wherein the OSM sample is used as input, and the actual lithography exposure and development are performed while inputting complete lithography exposure and development model including SMTM. The measured exposed silicon wafer result is compared with the simulated silicon wafer result, and the parameters in SMTM are iteratively adjusted based on the comparison result until the difference between the silicon wafer results output by the two is small enough, that is, the SMTF realized by the physical PIS is consistent with the one realized by the established model, then the established SMTM may be used as the PIS model. In the case where the measured RSM of the physical PIS cannot be directly observed, the PIS simulation method provided by the embodiment of the present disclosure includes the following steps S31 to S36.

Step S31: Preliminarily establishing an SMTM model. The model may be, but is not limited to, a combination of various eigen values and eigenfunctions, and adjustable parameters may be involved.

Step S32: Collecting data sets related to input OSM samples and measured silicon wafer result as reference data through the actual lithography exposure and development process. The input OSM data should be OSM samples of a plurality of different types, different configurations, and different parameters. The plurality of OSM samples involve various source maps as many as possible that may be realized by the physical PIS. After inputting each OSM sample into the physical PIS for undergoing optical exposure and resist reaction, the actual exposed silicon wafer result is observed. The OSM may be characterized by but not limited to image characterization, or using approximately orthogonal polynomials as basic functions, while the polynomials include but are not limited to Zernike polynomials, Legendre polynomials, etc. The silicon wafer result may be characterized by, but are not limited to, resist contours, feature sizes of various parts of the silicon wafer, etc.; when performing optical exposure, a mask is required, and one or a group of specially designed masks may be used for mask characterization. The disclosure provides no limitation to the mask characterization method.

Step S33: Using each OSM sample in step S32 as input data for the SMTM of step S31, and the output simulated RSM is used as the input of the optical exposure model, as well as the output of the optical exposure model is used as the input of the resist model to output the simulated silicon wafer result; the simulated silicon wafer result is characterized in the same way as the characterization method used for the actual silicon wafer result in step S32.

It is worth mentioning that the optical exposure model and resist model are established and calibrated models, and have the ability to describe the optical exposure process and resist reaction process in the actual exposure and development process. The model establishment and calibration methods may adopt existing model establishment and calibration methods, and the present disclosure is not limited by these two modeling and calibration methods described above.

Step S34: Differentiating the simulated silicon wafer result in each group with the measured silicon wafer result to make a comparison, and it is determined whether the difference (i.e., the second difference comparison result) is less than a predetermined threshold. If the difference is not less than the threshold, step S35 is performed; if the difference is less than the threshold, step S36 is performed.

Step S35: Adjusting the adjustable parameters in SMTM, updating SMTM, and performing step S33.

Step S36: Stopping iteration and outputting SMTM as the PIS model.

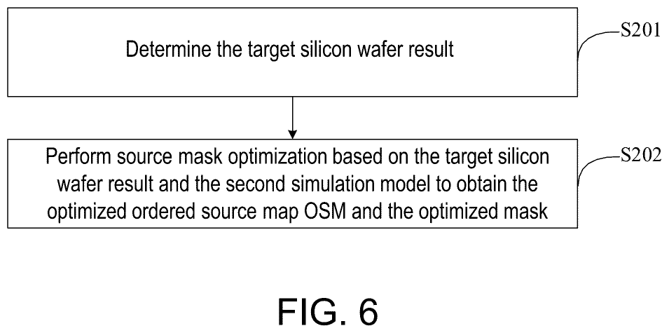

FIG. 6 is a schematic flow chart of a source mask optimization method according to an embodiment of the present disclosure. As shown in FIG. 6, an embodiment of the present disclosure further provides a source mask optimization method. The method may be directed at an electronic device, such as servers, etc. The method includes the following steps S201 and S202.

Step S201: Determining the target silicon wafer result (that is, the desired silicon wafer surface result).

Step S202: Performing source mask optimization based on the target silicon wafer result and the second simulation model to obtain the optimized ordered source map OSM and the optimized mask.

The second simulation model is constructed based on the PIS model, the optical exposure model and the resist model. The PIS model is obtained by applying any of the above simulation methods for the programmable illumination system.

It may be understood that after obtaining the calibrated SMTM (that is, the PIS model), the PIS model may be used in SMO to optimize the ordered source map, so that as the final SMO optimization result, the optimized OSM may be directly used as the input of the physical PIS. In this way, when IC manufacturers adopt the existing SMO source results as the source settings for physical PIS in practice, the problem of undesirable lithography exposure results caused by distortion of the physical PIS may be solved, thereby effectively improving processing window ultimately.

In a possible implementation, the second simulation model includes a first-stage simulation model and a second-stage simulation model. The first-stage simulation model is constructed based on the optical exposure model and the resist model, and the PIS model serves as the second-stage simulation model.

The step of performing the source mask optimization based on the target silicon wafer result and the second simulation model to obtain the optimized OSM and the optimized mask includes:
Performing the source mask optimization based on the target silicon wafer result and the first-stage simulation model to obtain the target RSM and optimized mask;
Obtaining the optimized OSM through iterative optimization based on the target RSM and the second-stage simulation model.

Optionally, the step of obtaining the optimized OSM through iterative optimization based on the target RSM and the second-stage simulation model specifically includes:
Inputting the target OSM into the PIS model to obtain the RSM output by the PIS model, wherein the initial target OSM is the target RSM;
Comparing the difference between the simulated RSM output by the PIS model and the target RSM (the comparison may be made through the pre-configured second-stage objective function), and determining the second-stage difference comparison result;
In the case where the second-stage difference comparison result indicates that the iteration stop condition is not met, adjusting the target OSM based on the second-stage difference comparison result; alternatively, in the case where the second-stage difference comparison result indicates that the iteration stop condition is met, determining the target OSM as the optimized OSM.

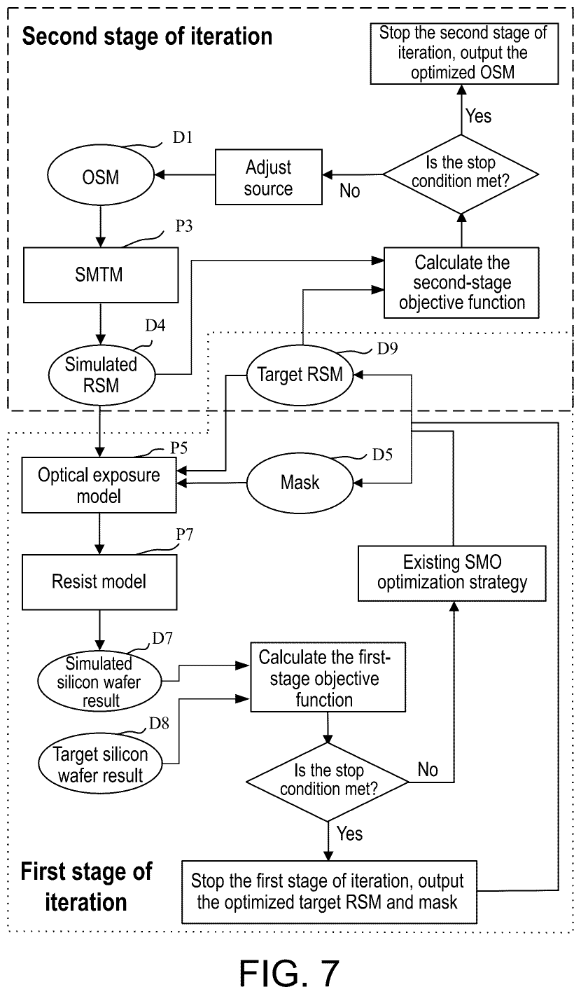

Example 4. FIG. 7 is a schematic flow chart of a two-stage SMO according to an embodiment of the present disclosure. As shown in FIG. 7, the two-stage SMO divides the entire SMO process into two iteration stages. In the first iteration stage, the existing SMO optimization strategy is adopted to iteratively optimize the source map and mask, and the source optimization result in the first iteration stage serves as the target RSM in the second iteration process. Through the second iteration stage, OSM that may actually be input into PIS is optimized and obtained. Specifically, the SMO method provided by an embodiment of the present disclosure includes the following steps S41 to S43.

Step S41: Using any of the above PIS simulation methods to obtain SMTM as the PIS model.

Step S42: Performing the first stage of iteration by using existing SMO technology to obtain the optimal source map and optimal mask.

The source map may be characterized by but not limited to image characterization, or may be decomposed and characterized using approximately orthogonal polynomials as basic functions, while the polynomials include but are not limited to Zernike polynomials, Legendre polynomials, etc. The mask may be characterized by, but is not limited to, pixel characterization, vertex characterization, etc.; the implementation of the present disclosure is not limited by source map characterization and mask characterization.

Step S42 specifically includes the following steps S42.1 to S42.6.

Step S42.1: Setting the initial source map and initial mask shape as the initial target RSM and mask.

Step S42.2: Defining the first-stage objective function. The objective function may be defined as the difference between the simulated silicon wafer result and the target silicon wafer result. The objective function may also be defined by increasing the process window as the optimization goal. The specific expression of the objective function is defined by the difference between the simulated silicon wafer result and the target silicon wafer result. Edge placement error (EPE) or edge contour error is used as the evaluation function to measure the quality of graphics correction. EPE is defined as the difference on evaluation points between the designed exposure contours at the target silicon wafer surface result and the simulation ones. The smaller the EPE, the closer the pattern after simulation and exposure and development is to the designed target pattern. Through defining the objective function by increasing the process window as the optimization goal, and calculating the process window corresponding to the source and mask, it is possible to ensure the exposure dose and defocus range at which the mask pattern is able to be correctly copied to the silicon wafer. The larger the process window, the better the optimization effect.

Step S42.3: Inputting the target RSM and mask into the optical exposure model, using the output of the optical exposure model as the input of the resist model, and outputting the simulated silicon wafer result (that is, the first-stage simulation model is constructed based on the optical exposure model and the resist model). The silicon wafer result may be characterized by, but are not limited to, resist contours, feature sizes of various parts of the silicon wafer, etc. Correspondingly, different characterization methods correspond to different specific expressions of the objective function. It is worth mentioning that the optical exposure model and resist model are established and calibrated models, and have the ability to describe the optical exposure process and resist reaction process in the actual exposure and development process. The model establishment and the calibration method may adopt existing model establishment and calibration methods, and the present disclosure is not limited to these two modeling and calibration methods described above.

Step S42.4: Calculating the first-stage objective function according to the first-stage objective function definition in step S42.2; determining whether the iteration stop condition is met: if the result is “No”, performing step S42.5; if the result is “Yes”, then performing step S42.6; wherein the iteration stop condition may be, but is not limited to, one or more of the following: the objective function value being less than the predetermined threshold; the number of iterations reaching the preset maximum number of iterations in the first stage.

Step S42.5: Using the existing SMO optimization strategy according to the objective function calculated in step S42.4 to optimally adjust the target RSM and mask, then performing step S42.3; wherein the existing SMO optimization strategy includes but is not limited to: the mask is optimized and then the source is optimized individually; the source is optimized and then the mask is optimized individually; source and mask are optimized together; source and mask are optimized alternately. The implementation of the present disclosure is not limited by the existing SMO optimization strategy; the specific optimization method in the existing optimization strategy may be, but is not limited to, the least squares method, regularization, convex optimization and other methods. The implementation of the present disclosure is not limited by limitations on the optimization methods used.

Step S42.6: Stopping the first stage of iteration, and outputting the target RSM and mask (as the optimized mask) as the optimal source map and optimal mask for the first stage of iteration of step S42.

Step S43: Carrying out the second stage of iteration, using the optimal source map obtained in step S42 as the target RSM, and using the PIS model established in step S41 to solve the optimized OSM, which is the input OSM of the final physical lithographic tool. Step S43 specifically includes the following steps S43.1 to step S43.6.

Step S43.1: Using the target RSM obtained in step S42.6 as the initial OSM.

Step S43.2: Defining the second-stage objective function. The objective function may be defined as the difference between the simulated RSM and the target RSM. The difference between the two may be evaluated using but is not limited to 2-norm.

Step S43.3. Inputting the OSM into the SMTM established in step S41 (that is, the PIS model is used as the second-stage simulation model), and the calculated output as a simulated RSM.

Step S43.4: Comparing the difference between the simulated RSM obtained in step S43.3 and the target RSM, and calculating the second-stage objective function according to the definition in step S43.2; determining whether the iteration stop condition is met: if the result is “No”, then performing step S43.5; if the result is “yes”, then performing step S43.6; wherein the iteration stop condition may be, but is not limited to, one or more of the following: the objective function value being less than the predetermined threshold; the number of iterations reaching the preset maximum number of iterations in the second stage.

Step S43.5: Adjusting and updating the OSM according to the difference between the simulated RSM and the target RSM in step S43.4, then performing step S43.3; the step of adjusting and updating the OSM may be performed by using but not limited to the neural network backpropagation method, least squares method, regularization, convex optimization and other optimization methods.

Step S43.6: Stopping the second stage of iteration and outputting the OSM as the optimized OSM, which is the source optimization result of SMO.

In a possible implementation, the second simulation model consists of a PIS model, an optical exposure model and a resist model sequentially cascaded. The step of performing source mask optimization based on the target silicon wafer result and the second simulation model to obtain the optimized OSM and optimized mask includes:
Inputting the target OSM into the PIS model, inputting the output amount of the PIS model and the target mask into the optical exposure model, inputting the output amount of the optical exposure model into the photoresist model to obtain the simulated silicon wafer result output by the photoresist model;
Comparing the difference between the simulated silicon wafer result and the target silicon wafer result (the comparison may be made through a pre-configured objective function), and determining the third difference comparison result;
In the case where the third difference comparison result indicates that the iteration stop condition is not met, adjusting the target OSM and the target mask based on the third difference comparison result; alternatively, in the case where the third difference comparison result indicates that the iteration stop condition is met, determining the target OSM as the optimized OSM and the determining the target mask as the optimized mask.

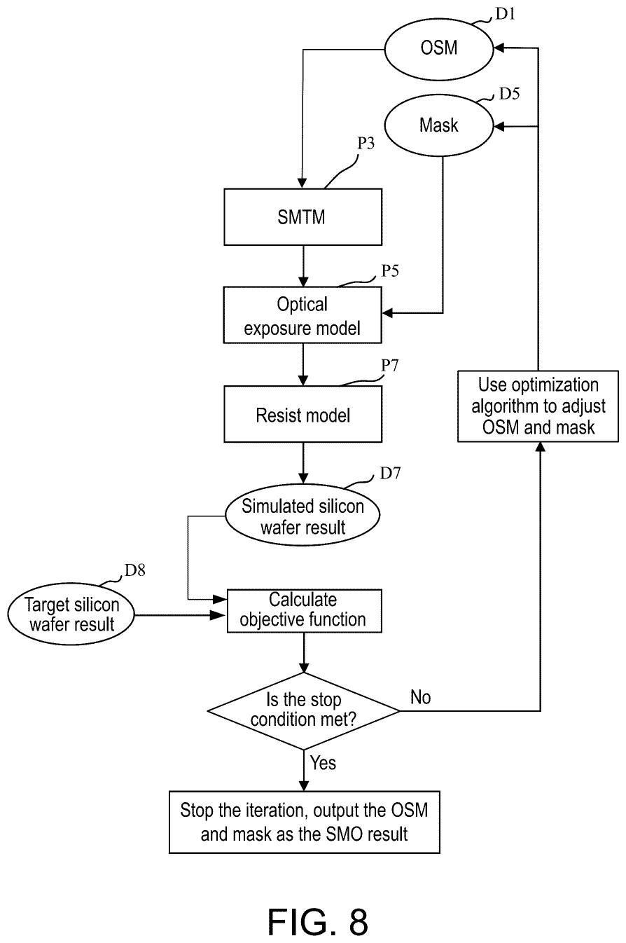

Example 5. FIG. 8 is a schematic flow chart of SMO including a PIS model according to an embodiment of the present disclosure. As shown in FIG. 8, the SMO method provided by an embodiment of the present disclosure includes the following steps S51 to step S53.

Step S51: Using any of the above PIS simulation methods to obtain SMTM as the PIS model.

Step S52: Establishing an SMO framework including the PIS model of step S51 with OSM and mask as optimization targets. The entire framework includes a forward process and a reverse process.

The forward process of the SMO framework includes: taking OSM as the input of SMTM, SMTM outputs RSM; RSM and mask are taken as the input of the optical exposure model, the output spatial image is used as the input of the resist model, and the output is the simulated silicon wafer result. The OSM may be characterized by but not limited to image characterization, or approximately orthogonal polynomials as basic functions. The mask may be characterized by, but is not limited to, pixel characterization, vertex characterization, etc. It is worth mentioning that the optical exposure model and resist model are established and calibrated models, and have the ability to describe the optical exposure process and resist reaction process in the actual exposure and development process. The model establishment and calibration methods may adopt existing model establishment and calibration methods, and the present disclosure is not limited by these two modeling and calibration methods described above.

The reverse optimization process of the SMO is performed by using optimization strategies and algorithms to adjust the OSM and the mask according to the objective function. The optimization strategy may include but is not limited to the following: the OSM is optimized and then the mask is optimized individually; the mask is optimized and then the OSM is optimized individually; the OSM and the mask are optimized together; the OSM and the mask are optimized alternately. The optimization algorithm may include but is not limited to least squares method, regularization, convex optimization and other methods.

Step S53: The step of using an iterative optimization method to perform SMO to obtain the optimal OSM and the optimal mask specifically includes the following steps S53.1 to S53.6.

Step S53.1: Setting the initial source map (as the initial target OSM) and the initial mask (as the initial target mask); optionally, the initial mask may be set to the pattern of the target silicon wafer surface result;

Step S53.2: Defining the SMO objective function. The objective function may be defined as the difference between the simulated silicon wafer result and the target silicon wafer result. The objective function may also be defined by increasing the process window as the optimization goal. The specific expression of the objective function is defined by the difference between the simulated silicon wafer result and the target silicon wafer result. Edge placement error (EPE) or edge contour error is used as the evaluation function to measure the quality of graphics correction. EPE is defined as the difference on evaluation points between the designed exposure contours at the target silicon wafer surface result and the simulation. The smaller the EPE, the closer the pattern after simulation and exposure and development is to the designed target pattern. Through defining the objective function by increasing the process window as the optimization goal, and calculating the process window corresponding to the source and mask, it is possible to ensure the exposure dose and defocus range at which the mask pattern is able to be correctly copied to the silicon wafer. The larger the process window, the better the optimization effect.

Step S53.3: Inputting the OSM into the SMTM, inputting the output of the SMTM and the mask into the optical exposure model, using the output of the optical exposure model as the input of the resist model, and outputting the simulated silicon wafer result.

Step S53.4: Calculating the objective function (the objective function value is used as the third difference comparison result) according to the objective function definition in step S53.2 and the simulated silicon wafer result obtained in step S53.3; determining whether the iteration stop condition is met: If the result is “No”, performing step S53.5; if the result is “Yes”, performing step S53.6; wherein the iteration stop condition may be, but is not limited to, one or more of the following: objective function value being less than the predetermined threshold; the number of iterations reaching the preset maximum number of iterations in the first stage.

Step S53.5: Using the SMO optimization strategy and optimization algorithm to optimize and adjust the OSM and mask (that is, adjust the target OSM and target mask), and performing step S53.3.

Step S53.6: Stopping the iteration and outputting the OSM (as the optimized OSM) and the mask (as the optimized mask). The optimized OSM and the optimized mask constitute the SMO optimization result.

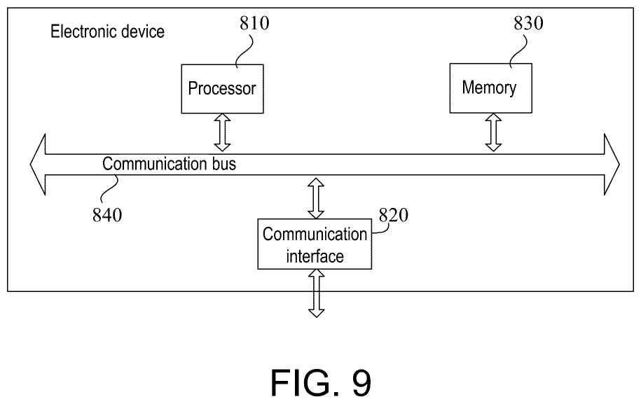

Based on the method in the above embodiment, the embodiment of the present disclosure provides an electronic device. FIG. 9 is a schematic structural diagram of the electronic device provided by the embodiment of the present disclosure. As shown in FIG. 9, the electronic device may include: a processor 810, a communication interface 820, a memory 830, and a communication bus 840. The processor 810, the communication interface 820, and the memory 830 complete communication with each other through the communication bus 840. The processor 810 may invoke logical instructions in the memory 830 to execute the method in the above embodiments.

In addition, the logical instructions in the memory 830 may be implemented in the form of software functional units and may be stored in a computer-readable storage medium when being sold or used as an independent product. Based on this understanding, essentially the technical solution of the present disclosure or the part that contributes to the existing technology or a part of the technical solution may be embodied in the form of a software product. The computer software product is stored in a storage medium, including several instructions that are used to make a computer device (which may be a personal computer, a server, or a network device, etc.) to execute all or part of the steps of the methods described in various embodiments of the present disclosure.

Based on the methods in the above embodiments, embodiments of the present disclosure provide a computer-readable storage medium. The computer-readable storage medium stores a computer program. When the computer program is run on a processor, the processor is enabled to execute the methods in the above embodiments.

Based on the methods in the above embodiments, embodiments of the present disclosure provide a computer program product, which enables a processor to execute the methods in the above embodiments when being run on the processor.

It can be understood that the processor in the embodiment of the present disclosure may be a central processing unit (CPU), or other general-purpose processor, digital signal processor (DSP), application-specific integrated circuit (ASIC), field programmable gate array (FPGA) or other programmable logic devices, transistor logic devices, hardware components or any combination of the above. A general-purpose processor may be a microprocessor or any conventional processor.

The methods and steps in the embodiments of the present disclosure may be implemented by hardware or by a processor executing software instructions. Software instructions may be composed of corresponding software modules, which may be stored in a random access memory (RAM), a flash memory, a read-only memory (ROM), a programmable ROM (PROM), an erasable PROM (EPROM), an electrically EPROM (EEPROM), a register, a hard disk, a mobile hard disk, a CD-ROM or other storage media commonly known in the art in any other form. An exemplary storage medium is coupled to the processor such that the processor is able to read information from the storage medium and write information to the storage medium. Of course, the storage medium may also be an integral part of the processor. The processor and storage media may be located in an ASIC.

The above embodiments may be implemented, in whole or in part, by software, hardware, firmware, or any combination thereof. When the above embodiments are implemented using software, they may be implemented, in whole or in part, in the form of a computer program product. The computer program product includes one or more computer instructions. When the computer program instructions are loaded and executed on a computer, the processes or functions described in the embodiments of the present disclosure are generated in whole or in part. The computer may be a general-purpose computer, a specific-purpose computer, a computer network, or other programmable device. The computer instructions may be stored in or transmitted over a computer-readable storage medium. The computer instructions may be transmitted from one website, computer, server or data center to another website, computer, server or data center in a wired manner (such as coaxial cable, optical fiber, digital subscriber line (DSL)) or wireless manner (such as infrared, wireless, microwave, etc.). The computer-readable storage medium may be any available medium that may be accessed by a computer or a data storage device such as a server, data center, etc. that contains one or more available integrated media. The available media may be magnetic media (e.g., floppy disk, hard disk, magnetic tape), optical media (e.g., DVD), or semiconductor media (e.g., solid state disk (SSD)), etc.

It can be understood that the various numerical numbers involved in the embodiments of the present disclosure are only for convenience of description and are not used to limit the scope of the embodiments of the present disclosure.

It is easy for those skilled in the art to understand that the above descriptions are only preferred embodiments of the present disclosure and are not intended to limit the present disclosure. Any modifications, equivalent substitutions and improvements, etc., made within the spirit and principles of the present disclosure should all be included in the scope to be protected by the disclosure.

What is claimed is:

1. A simulation method for a programmable illumination system (PIS), comprising:
calibrating parameters of a source map transfer model (SMTM) in a first simulation model based on an ordered source map (OSM) sample and an actual processing result; wherein the actual processing result is obtained by inputting the OSM sample to a physical lithographic tool and monitoring a processing process of the physical lithographic tool, wherein the physical lithographic tool is equipped with a PIS entity, and the first simulation model is configured to output a simulation processing result corresponding to the actual processing result, the first simulation model at least comprises the SMTM;
wherein a calibrated SMTM is used as a PIS model; the PIS model is used to simulate the PIS entity.

2. The simulation method for the PIS according to claim 1, wherein when a realized source map (RSM) output by a physical PIS entity is able to be observed, the actual processing result is a measured RSM of the physical PIS entity, the first simulation model is the SMTM, and the simulation processing result is a simulated RSM output by the SMTM;
wherein the step of calibrating the parameters of the SMTM in the first simulation model based on the OSM sample and the actual processing result comprises:
continuously optimizing the SMTM based on the OSM sample and an RSM output by the physical PIS entity until an iteration stop condition is met;
wherein the step of optimizing the SMTM comprises:
inputting the OSM sample to the SMTM to obtain the simulated RSM output by the SMTM;
comparing a difference between the measured RSM of the physical PIS entity and the simulated RSM output by the SMTM to determine a first difference comparison result;
when the first difference comparison result indicates that the iteration stop condition is not met, adjusting the parameters of the SMTM based on the first difference comparison result; when the first difference comparison result indicates that the iteration stop condition is met, determining the calibrated SMTM.

3. The simulation method for the PIS according to claim 2, wherein the SMTM is a neural network model, and the step of comparing the difference between the RSM output by the PIS entity and the RSM output by the SMTM to determine the first difference comparison result comprises:
determining a first difference between the RSM output by the PIS entity and the RSM output by the SMTM; evaluating the first difference based on a loss function and determining a loss value as the first difference comparison result;
when the first difference comparison result indicates that the iteration stop condition is not met, the step of adjusting the parameters of the SMTM based on the first difference comparison result comprises:
adjusting network neuron weights of the neural network model through backpropagation based on the loss value.

4. The simulation method for the PIS according to claim 1, wherein when a realized source map RSM output by the physical PIS entity is not able to be observed, the first simulation model comprises the SMTM, an optical exposure model and a resist model cascaded in sequence, and the simulation processing result is a simulated silicon wafer result output by the resist model;
wherein the step of calibrating the parameters of the SMTM in the first simulation model based on the OSM sample and the actual processing result comprises:
continuously optimizing the SMTM based on the OSM sample and an actual silicon wafer result output by the physical lithographic tool until an iteration stop condition is met;
wherein the step of optimizing the SMTM comprises:
inputting the OSM sample into the first simulation model to obtain the simulated silicon wafer result output by the resist model;
comparing a difference between the actual silicon wafer result output by the physical lithographic tool and the simulated silicon wafer result output by the resist model, and determining a second difference comparison result;
when the second difference comparison result indicates that the iteration stop condition is not met, adjusting the parameters of the SMTM based on the second difference comparison result; when the second difference comparison result indicates that the iteration stop condition is met, determining the calibrated SMTM.

5. A source mask optimization method, comprising:
determining a target silicon wafer result;
performing source mask optimization based on the target silicon wafer result and a second simulation model to obtain an optimized OSM and an optimized mask;
wherein the second simulation model is constructed based on the PIS model, an optical exposure model and a resist model, and the PIS model is obtained by applying the simulation method for the PIS according to claim 1.

6. The source mask optimization method according to claim 5, wherein the second simulation model comprises a first-stage simulation model and a second-stage simulation model, the first-stage simulation model is constructed based on the optical exposure model and the resist model, and the PIS model serves as the second-stage simulation model;
wherein the step of performing the source mask optimization based on the target silicon wafer result and the second simulation model to obtain the optimized OSM and the optimized mask comprises:
performing the source mask optimization based on the target silicon wafer result and the first-stage simulation model to obtain a target RSM and the optimized mask;
obtaining an optimized OSM through iterative optimization based on the target RSM and the second-stage simulation model.

7. The source mask optimization method according to claim 6, wherein the step of obtaining the optimized OSM through the iterative optimization based on the target RSM and the second-stage simulation model comprises:
inputting a target OSM into the PIS model, obtaining an RSM output by the PIS model, wherein an initial target OSM is the target RSM;
comparing a difference between the RSM output by the PIS model and the target RSM, and determining a second-stage difference comparison result;
when the second-stage difference comparison result indicates that an iteration stop condition is not met, adjusting the target OSM based on the second-stage difference comparison result; alternatively, when the second-stage difference comparison result indicates that the iteration stop condition is met, determining the target OSM as the optimized OSM.

8. The source mask optimization method according to claim 5, wherein the second simulation model consists of the PIS model, the optical exposure model and the resist model cascaded in sequence, wherein the step of performing the source mask optimization based on the target silicon wafer result and the second simulation model to obtain the optimized OSM and the optimized mask comprises:
inputting a target OSM to the PIS model, inputting an output amount of the PIS model and a target mask to the optical exposure model, inputting an output amount of the optical exposure model to the resist model to obtain a simulated silicon wafer result output by the resist model;
comparing a difference between the simulated silicon wafer result and the target silicon wafer result, and determining a third difference comparison result;
when the third difference comparison result indicates that an iteration stop condition is not met, adjusting the target OSM and the target mask based on the third difference comparison result; alternatively, when the third difference comparison result indicates that the iteration stop condition is met, determining the target OSM as the optimized OSM and determining the target mask as the optimized mask.

9. An electronic device, comprising:
at least one memory for storing a computer program;
at least one processor for executing a program stored in the memory, wherein when the program stored in the memory is executed, the processor is configured to execute the method according to claim 1.

10. A computer-readable storage medium, which stores a computer program, wherein when the computer program is run on a processor, the processor is enabled to execute the method according to claim 1.
